(19) United States
(12) Patent Application Publication
(10) Pub. No.: US 2019/0392762 A1
(43) Pub. Date: Dec. 26, 2019

(54) Display Device

(71) Applicant: Panasonic Liquid Crystal Display Co., Ltd., Hyogo (JP)

(72) Inventors: Tetsuya KAWAMURA, Hyogo (JP); Yoshihiro IMAJO, Hyogo (JP)

(21) Appl. No.: 16/442,558

(22) Filed: Jun. 17, 2019

(30) Foreign Application Priority Data
Jun. 22, 2018 (JP) 2018119172

(51) Int. Cl. G09G 3/3258; H01L 27/12

(52) U.S. Cl. CPC G09G 3/3258; H01L 27/124

(57) ABSTRACT

A display device comprising: a first substrate; and a first TFT array and a second TFT array that are formed on the first substrate, wherein the first TFT array includes: a plurality of first gate lines extending in a first direction; and a plurality of first source lines extending in a second direction intersecting the first direction, the second TFT array includes: a plurality of second gate lines extending in one of the first direction and the second direction; and a plurality of second source lines extending in the other of the first direction and the second direction, and the first TFT array and the second TFT array are electrically isolated from each other, and disposed adjacent to each other in the first direction.

### CROSS-REFERENCE TO RELATED APPLICATION

This application claims priority from Japanese application JP 2018-119172, filed Jun. 22, 2018. This Japanese application is incorporated herein by reference.

BACKGROUND

### 1. Technical Field

The present disclosure relates to a display device.

### 2. Description of the Related Art

Unexamined Japanese Patent Publication No. 2015-180924 discloses a display device including a plurality of display panels formed on different substrates. Each display panel includes a display region including a TFT array and a frame region formed around the display region, and frame regions of the plurality of display panels are disposed while being overlapped with each other, thereby constituting one display device.

### SUMMARY

In the above configuration, because of presence of the frame region between the plurality of display panels, a boundary between the plurality of TFT arrays is conspicuous to degrade designability.

The present disclosure has been made in view of the above problems, and an object of the present disclosure is to reduce visibility of the boundary between the plurality of TFT arrays to improve the designability in the display device including the plurality of TFT arrays.

To solve the above problem, a display device according to a present disclosure comprises: a first substrate; and a first TFT array and a second TFT array that are formed on the first substrate, wherein the first TFT array includes: a plurality of first gate lines extending in a first direction; and a plurality of first source lines extending in a second direction intersecting the first direction, the second TFT array includes: a plurality of second gate lines extending in one of the first direction and the second direction; and a plurality of second source lines extending in the other of the first direction and the second direction, and the first TFT array and the second TFT array are electrically isolated from each other, and disposed adjacent to each other in the first direction.

The display device according to the present disclosure can reduce visibility of the boundary between the plurality of TFT arrays to improve the designability in the display device including the plurality of TFT arrays.

### BRIEF DESCRIPTION OF DRAWINGS

FIG. 1 is a schematic diagram illustrating a configuration of display device according to an exemplary embodiment.

FIG. 2 is an enlarged schematic diagram illustrating a boundary portion between first TFT array and second TFT array in FIG. 1.

FIG. 3 is a schematic diagram illustrating a configuration of display device according to another example of the exemplary embodiment.

FIG. 4 is a sectional view which is taken along first gate line in FIG. 3 and illustrates a part of a vertical section of first substrate.

FIG. 5 is an enlarged schematic diagram illustrating the boundary portion between first TFT array and second TFT array in FIG. 3.

FIG. 6 is a schematic diagram illustrating a configuration of display device according to another example of the exemplary embodiment.

FIG. 7 is a schematic diagram illustrating a configuration of display device according to another example of the exemplary embodiment.

FIG. 8 is a schematic diagram illustrating a configuration in which an end side extending in the second direction is curved in the first substrate according to the exemplary embodiment.

FIG. 9 is an enlarged schematic diagram illustrating the boundary portion between first TFT array and third TFT array in FIG. 7.

FIG. 10 is a schematic diagram illustrating a configuration of display device according to another example of the exemplary embodiment.

FIG. 11 is a schematic diagram illustrating a configuration in which an end side extending in the first direction is curved in the first substrate according to the exemplary embodiment.

FIG. 12 is an enlarged schematic diagram illustrating the boundary portion between first TFT array and third TFT array in FIG. 10.

FIG. 13 is a schematic diagram to explain a drive rate.

FIG. 14 is a schematic diagram to explain a drive rate.

FIG. 15 is a schematic diagram illustrating a configuration of display device according to another example of the exemplary embodiment.

FIG. 16 is a schematic diagram illustrating an arrangement of common electrodes of the display device according to the exemplary embodiment.

FIG. 17 is a conceptual view illustrating gradation characteristic in the display device according to the exemplary embodiment.

FIG. 18 is a conceptual view illustrating relationship between voltage output from gate driver and time in the display device according to the exemplary embodiment.

FIG. 19 is a schematic diagram illustrating an arrangement example of liquid crystal layer and seal member according to the exemplary embodiment.

FIG. 20 is a schematic diagram illustrating an arrangement example of liquid crystal layer and seal member according to another example of the exemplary embodiment.

FIG. 21 is a schematic diagram illustrating an arrangement example of liquid crystal layer and seal member according to another example of the exemplary embodiment.

### DETAILED DESCRIPTION

### Exemplary Embodiment

Hereinafter, an exemplary embodiment of the present disclosure will be described with reference to the drawings. In the exemplary embodiment, a liquid crystal display device is described as an example of display device. However the present disclosure is not limited to the liquid crystal display device. For example the present disclosure may be an organic electroluminescence display (OLED) device.

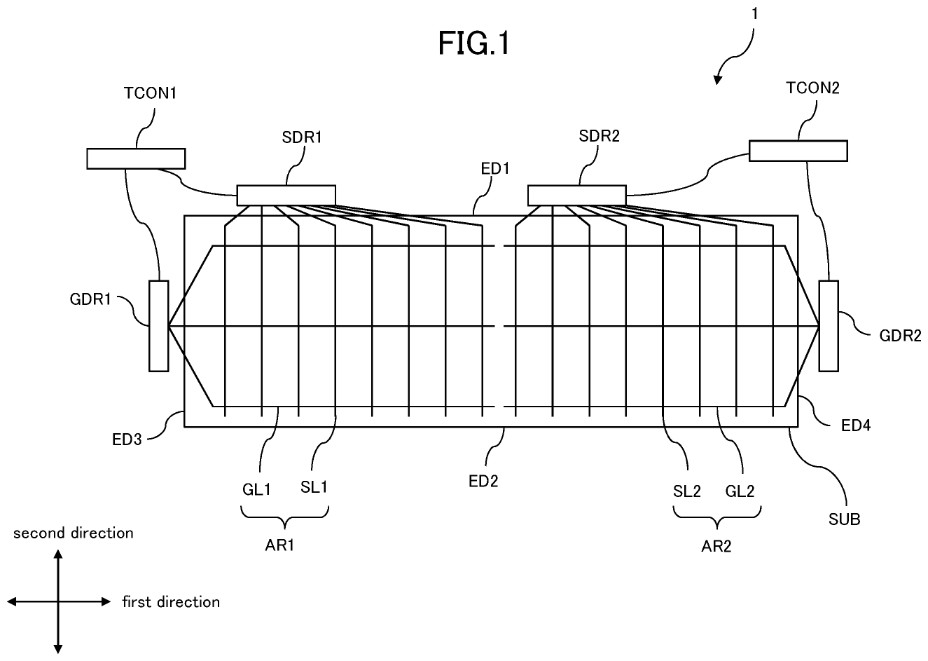

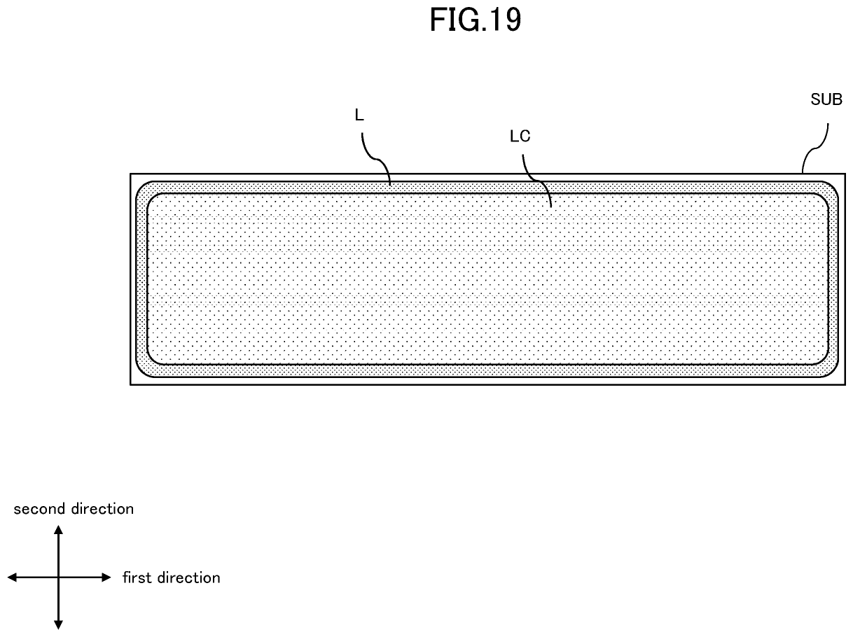

FIG. 1 is a schematic diagram illustrating a configuration of display device 1 according to an exemplary embodiment of the present disclosure. As illustrated in FIG. 1, display device 1 of the exemplary embodiment includes first substrate SUB that is a thin film transistor substrate, first TFT array AR1 formed in the first substrate SUB, and second TFT array AR2 formed in the first substrate SUB. First TFT array AR1 includes a plurality of first gate lines GL1 extending in a first direction and a plurality of first source lines SL1 extending in a second direction intersecting the first direction. Second TFT array AR2 includes a plurality of second gate lines GL2 extending in the first direction and a plurality of second source lines SL2 extending in the second direction. Display device 1 includes a counter substrate that is disposed opposite to first substrate SUB and includes a color filter and the like, and a liquid crystal layer disposed between the counter substrate and first substrate SUB. An arrangement example of the liquid crystal layer will be described later with reference to FIGS. 19, 20, and 21.

First TFT array AR1 and second TFT array AR2 are disposed adjacent to each other in the first direction. First TFT array AR1 and second TFT array AR2 are electrically isolated from each other. That is, first source driver SDR1 that supplies a source signal to first TFT array AR1 and first gate driver GDR1 that supplies a gate signal to first TFT array AR1 are not electrically connected to second source driver SDR2 that supplies the source signal to second TFT array AR2 and second gate driver GDR2 that supplies the gate signal to second TFT array AR2.

As described above, a configuration in which the boundary is hardly visually recognized between first TFT array AR1 and second TFT array AR2 can be constructed because first TFT array AR1 and second TFT array AR2 are formed in first substrate SUB.

Each TFT array (in the example of FIG. 1, first TFT array AR1 and second TFT array AR2) has a configuration connected to different drive circuit (in the example of FIG. 1, first source driver SDR1, first gate driver GDR1, second source driver SDR2, and second gate driver GDR2), so that the number of pixels can be increased as a whole of display device 1 beyond a restriction of the number of pixels in each drive circuit. It is not necessary to connect first timing controller TCON1 that controls drive of first source driver SDR1 and first gate driver GDR1 and second timing controller TCON2 that controls drive of second source driver SDR2 and second gate driver GDR2 to each other by wiring in order to synchronize first timing controller TCON1 and second timing controller TCON2 with each other, and a general-purpose timing controller can be used as first timing controller TCON1 and second timing controller TCON2.

Moreover, since first TFT array AR1 and second TFT array AR2 are electrically isolated from each other, an influence (for example, a non-display state) on the other can be prevented, for example, even if some sort of failure (such as a breakdown of the drive circuit) is generated in one of first TFT array AR1 and second TFT array AR2.

In the example of FIG. 1, first substrate SUB includes first end side ED1 and second end side ED2 that extend in the first direction, and third end side ED3 and fourth end side ED4 that extend in the second direction. First end side ED1 and second end side ED2 are disposed opposite to each other, and third end side ED3 and fourth end side ED4 are disposed opposite to each other.

First source driver SDR1 that supplies the source signal to first source line SL1 is disposed along first end side ED1. First gate driver GDR1 that supplies the gate signal to first gate line GL1 is disposed along third end side ED3. Second source driver SDR2 that supplies the source signal to second source line SL2 is disposed along first end side ED1. Second gate driver GDR2 that supplies the gate signal to second gate line GL2 is disposed along fourth end side ED4.

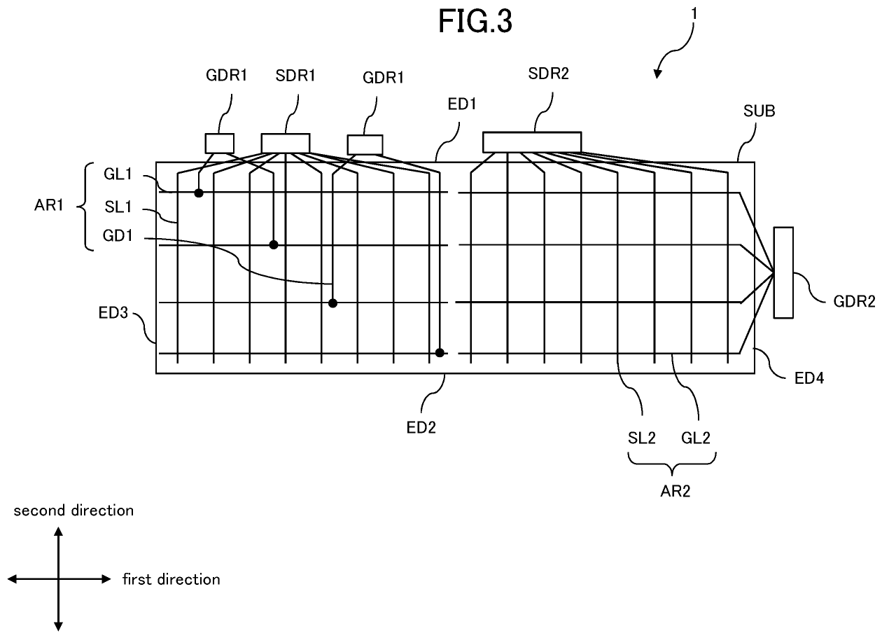

In the configuration of display device 1 of the exemplary embodiment, each drive circuit (first source driver SDR1, first gate driver GDR1, second source driver SDR2, and second gate driver GDR2) that displays an image is disposed along one of the end sides of first substrate SUB, which allows construction of the configuration in which each driver circuit is not disposed between first TFT array AR1 and second TFT array AR2. The configuration of so-called COF (Chip on Film) in which each drive circuit is formed on a film separate from first substrate SUB is described in the example of FIG. 1. However, the present disclosure is not limited to this configuration. For example, the configuration of so-called COG (Chip on Glass) in which first substrate SUB includes a glass substrate and each drive circuit is formed on first substrate SUB may be adopted. For the configuration of the COF, each drive circuit is disposed outside one of the end sides of first substrate SUB. For the configuration of the COG, each drive circuit is disposed inside one of the end sides of first substrate SUB. In both the configurations of the COF and COG, each drive circuit is disposed along one of the end sides of first substrate SUB. In the examples of FIG. 3 and subsequent figures, either of the COF and COG may be adopted.

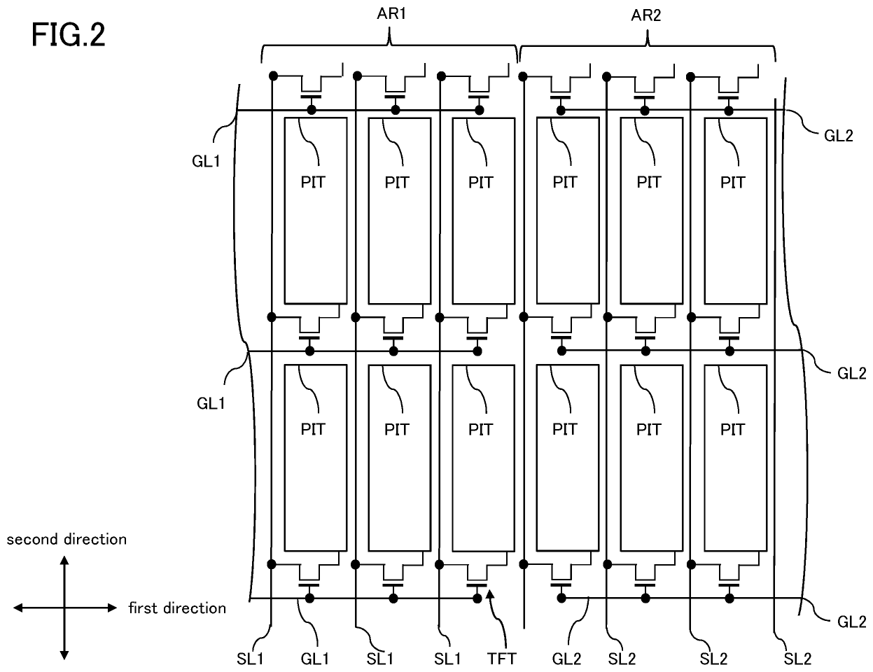

FIG. 2 is an enlarged schematic diagram illustrating a boundary portion between first TFT array AR1 and second TFT array AR2 in FIG. 1. As illustrated in FIG. 2, the plurality of first gate lines GL1 and the plurality of second gate lines GL2 extend in the first direction, and are arranged at identical intervals. That is, a distance in the second direction between two first gate lines GL1 adjacent to each other across pixel electrode PIT is equal to a distance in the second direction between two second gate lines GL2 adjacent to each other across pixel electrode PIT. In the examples of FIGS. 1 and 2, the distance in the first direction between two first source lines SL1 adjacent to each other across pixel electrode PIT in first TFT array AR1 is equal to the distance in the first direction between two second source lines SL2 adjacent to each other across pixel electrode PIT in second TFT array AR2. The distance in the first direction between first source line SL1 closest to second TFT array AR2 among the plurality of first source lines SL1 and second source lines SL2 closest to first TFT array AR1 among the plurality of second source lines SL2 is equal to the distance in the first direction between two first source lines SL1 adjacent to each other across pixel electrode PIT in first TFT array AR1. With this configuration, the visibility of the boundary between first TFT array AR1 and second TFT array AR2 can further be decreased. In FIG. 1, although the limited numbers of source lines and gate lines are illustrated for convenience, actually, display device 1 may have larger numbers of source lines and gate lines.

In the example of FIG. 1, first source driver SDR1 and second source driver SDR2 are disposed along first end side ED1. Alternatively, at least one of first source driver SDR1 and second source drivers SDR2 may be disposed along second end side ED2. However, space saving of the frame region is desirably achieved by the configuration in which first source driver SDR1 and second source driver SDR2 are disposed along the common end side (first end side ED1 or second end side ED2).

As illustrated in FIG. 3, first TFT array AR1 may further include a plurality of first gate lead-out lines GD1, which extend in the second direction and are connected to the plurality of first gate lines GL1. First gate lead-out line GD1 extends between two first source lines SL1 adjacent to each other. First gate driver GDR1 is connected to the plurality of first gate lead-out lines GD 1.

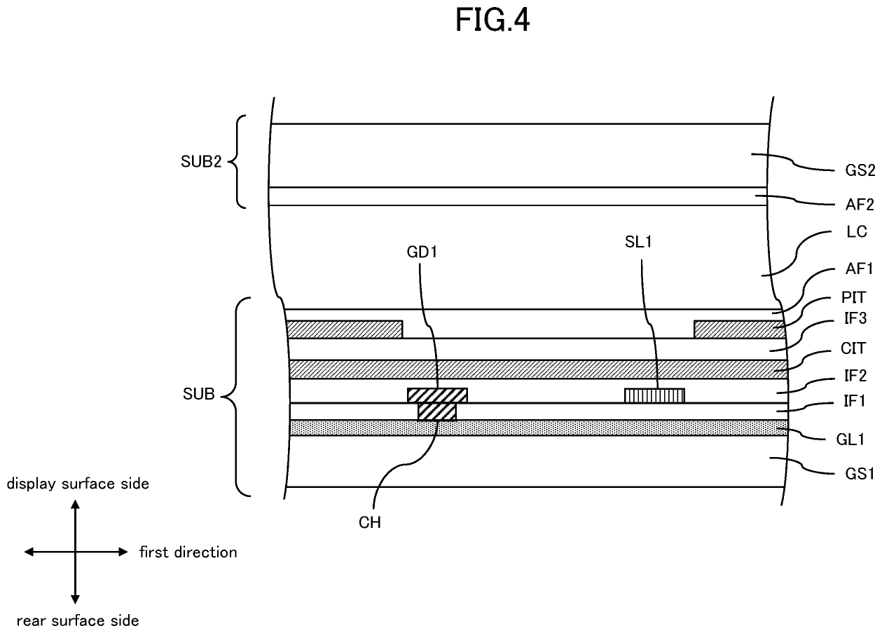

FIG. 4 is a sectional view which is taken along first gate line GL1 in FIG. 3 and illustrates a part of a vertical section of first substrate SUB. As illustrated in FIG. 4, first insulating film IF1 is interposed between the plurality of first gate lines GL1 formed on first glass substrate GS1 and the plurality of first gate lead-out lines GD1. One first gate lead-out line GD1 and one first gate line GL1 are electrically connected to each other through contact hole CH formed in first insulating film IF1. The gate signal output from first gate driver GDR1 is supplied to the plurality of first gate lines GL1 through the plurality of first gate lead-out lines GD1. In the exemplary embodiment, the plurality of first source lines SL1 are formed in the same layer as the plurality of first gate lead-out lines GD1, and second insulating film IF2 is formed so as to cover the plurality of first source lines SL1 and the plurality of first gate lead-out lines GD1. Common electrode CIT is formed on a display surface side of second insulating film IF2, and pixel electrode PIT is formed on the display surface side of common electrode CIT. Third insulating film IF3 is interposed between common electrode CIT and pixel electrode PIT. On the display surface side of third insulating film IF3, first alignment film AF1 is formed so as to cover pixel electrode PIT. Liquid crystal layer LC is disposed on the display surface side of first alignment film AF1. Second alignment film AF2 and counter substrate SUB2 including second glass substrate GS2 are disposed on the display surface side of liquid crystal layer LC. A color filter or a black matrix may be disposed between second glass substrate GS2 and second alignment film AF2.

As illustrated in FIG. 3, first TFT array AR1 includes the plurality of first gate lead-out lines GD1 which allows first gate driver GDR1 to be disposed along first end side ED1 or second end side ED2 extending in the first direction. As a result, the configuration in which each drive circuit is not disposed along the end side (in the example of FIG. 3, third end side ED3) extending in the second direction can be constructed, and the space saving of the frame region can desirably further be achieved along the end side extending in the second direction.

However, a wiring capacitance can be reduced when each TFT array does not include the gate lead-out line as illustrated in FIG. 1, which is desirable from the viewpoint of high speed drive.

In the example of FIG. 3, second gate driver GDR2 is disposed along fourth end side ED4 extending in the second direction, and second source driver SDR2 is disposed along the end side (in the example of FIG. 3, first end side ED1) extending in the first direction. Alternatively, at least one of first source driver SDR1, first gate driver GDR1, and second source drivers SDR2 may be disposed along second end side ED2. However, the space saving of the frame region can desirably be achieved when first source driver SDR1, first gate driver GDR1, and second source driver SDR2 are disposed along a common end side (first end side ED1 or second end side ED2).

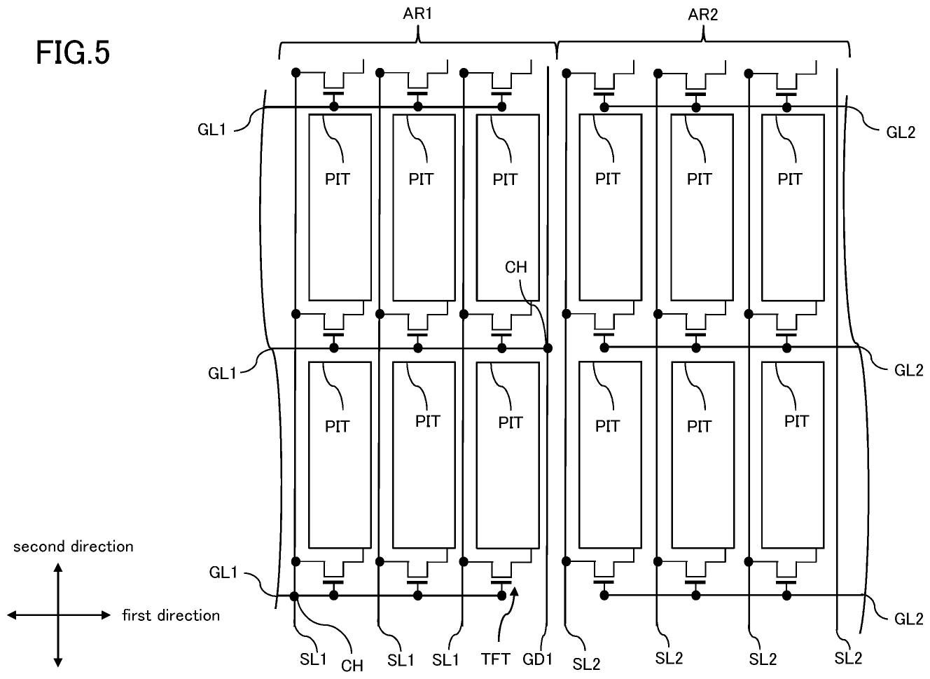

FIG. 5 is an enlarged schematic diagram illustrating the boundary portion between first TFT array AR1 and second TFT array AR2 in FIG. 3. In the example of FIG. 5, in first TFT array AR1, first gate lead-out lines GD1 are disposed at a ratio of one first gate lead-out line GD1 to three pixel electrodes PIT arrayed in the first direction. First gate lead-out line GD1 is electrically connected to first gate line GL1 through contact hole CH. In the example of FIG. 5, the distance in the second direction between two first gate lines GL1 adjacent to each other across the pixel electrode PIT is equal to the distance in the second direction between two adjacent second gate lines GL2 adjacent to each other across pixel electrode PIT. The distance in the first direction between two first source lines SL1 between which three pixel electrodes PIT arrayed in the first direction in first TFT array AR1 are interposed is equal to the distance in the first direction between two second source lines SL2 between which three pixel electrodes PIT arrayed in the first direction in second TFT array AR2 are interposed. Similarly, in the boundary portion, the distance in the first direction between one first source line SL1 and one second source line SL2 between which three pixel electrodes PIT arrayed in the first direction are interposed is equal to the distance in the first direction between two second source lines SL2 between which three pixel electrodes PIT arrayed in the first direction are interposed. For example, among the plurality of second source lines SL2, the distance in the first direction between second source line SL2 closest to first TFT array AR1 and first source line SL1 disposed so as to interpose three pixel electrodes arrayed in the first direction with second source line SL2 is equal to the distance in the first direction between second source line SL2 closest to first TFT array AR1 and another second source lines SL2 disposed so as to interpose the three pixel electrodes arrayed in the first direction with second source line SL2. First TFT array AR1 includes first gate lead-out line GD1. On the other hand, second TFT array AR2 does not include the gate lead-out line. As a result, a width in the first direction of pixel electrode PIT in first TFT array AR1 is equal to a width in the first direction of pixel electrode PIT in second TFT array AR2. In FIG. 3, although the limited numbers of source lines and gate lines are illustrated for convenience, actually, display device 1 may have larger numbers of source lines and gate lines.

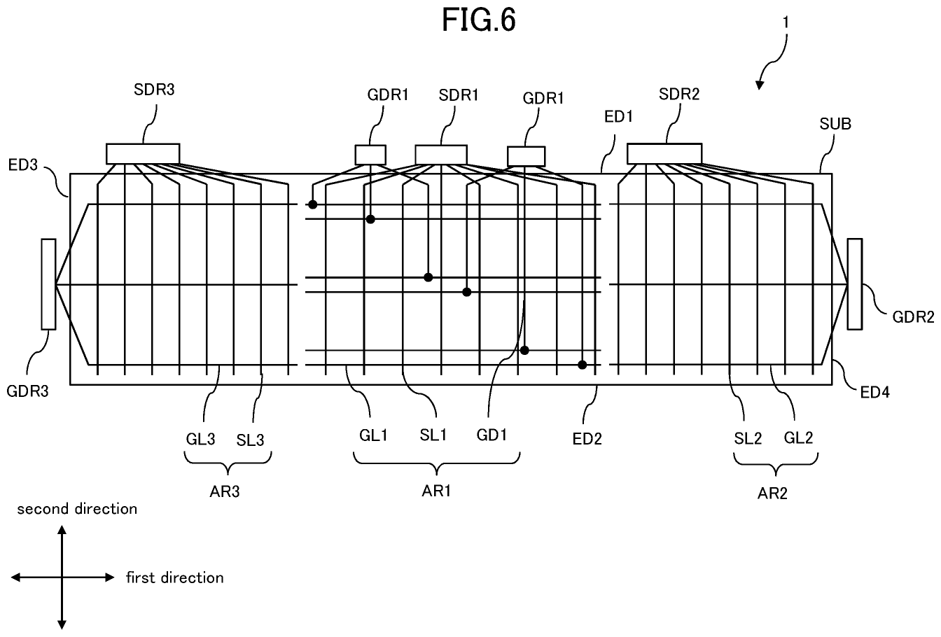

As illustrated in FIG. 6, display device 1 may further include third TFT array AR3, which is disposed adjacent to first TFT array AR1 and on the opposite side to second TFT array AR2 with respect to first TFT array AR1. In the example of FIG. 6, third TFT array AR3 includes a plurality of third gate lines GL3 extending in the first direction and a plurality of third source lines SL3 extending in the second direction. As described above, in the exemplary embodiment, the TFT array refers to a configuration including the plurality of source lines, the plurality of gate lines, and the plurality of thin film transistors connected to the plurality of source lines and the plurality of gate lines, and the TFT array may further include a plurality of gate lead-out lines.

Third TFT array AR3 is formed in first substrate SUB common to first TFT array AR1 and second TFT array AR2, and electrically isolated from first TFT array AR1 and second TFT array AR2. That is, third source driver SDR3 and third gate driver GDR3 that are included in third TFT array AR3 are not connected to first source driver SDR1 and first gate driver GDR1 that are included in first TFT array AR1 and second source driver SDR2 and second gate driver GDR2 that are included in second TFT array AR2.

As described above, a configuration in which the boundary is hardly visually recognized among the three TFT arrays can be constructed because first TFT array AR1, second TFT array AR2, and third TFT array AR3 are formed in first substrate SUB.

Each TFT array is connected to the separate drive circuit, so that the number of pixels can be increased as a whole of display device 1 beyond the restriction of the number of pixels in each drive circuit.

First TFT array AR1, second TFT array AR2, and third TFT array AR3 are electrically isolated from one another, so that the influence on the other TFT arrays can be prevented even if some sort of failure is generated in one of first TFT array AR1, second TFT array AR2, and third TFT arrays AR3.

In the example of FIG. 6, third gate driver GDR3 that supplies the gate signal to the plurality of third gate lines GL3 is disposed along the end side (in the example of FIG. 6, third end side ED3) opposed to the end side (in the example of FIG. 6, fourth end side ED4) disposed along second gate driver GDR2 among the end sides of first substrate SUB. Third source driver SDR3 that supplies the source signal to the plurality of third source lines SL3 is disposed along the end side (in the example of FIG. 6, first end side ED1) extending in the first direction among the end sides of first substrate SUB.

As described above, in the configuration of display device 1 of the exemplary embodiment, each drive circuit (first source driver SDR1, first gate driver GDR1, second source driver SDR2, second gate driver GDR2, third source driver SDR3, and third gate driver GDR3) that displays the image is disposed along one of the end sides of first substrate SUB, which allows construction of the configuration in which each driver circuit is not disposed among first TFT array AR1, second TFT array AR2, and third TFT array AR3.

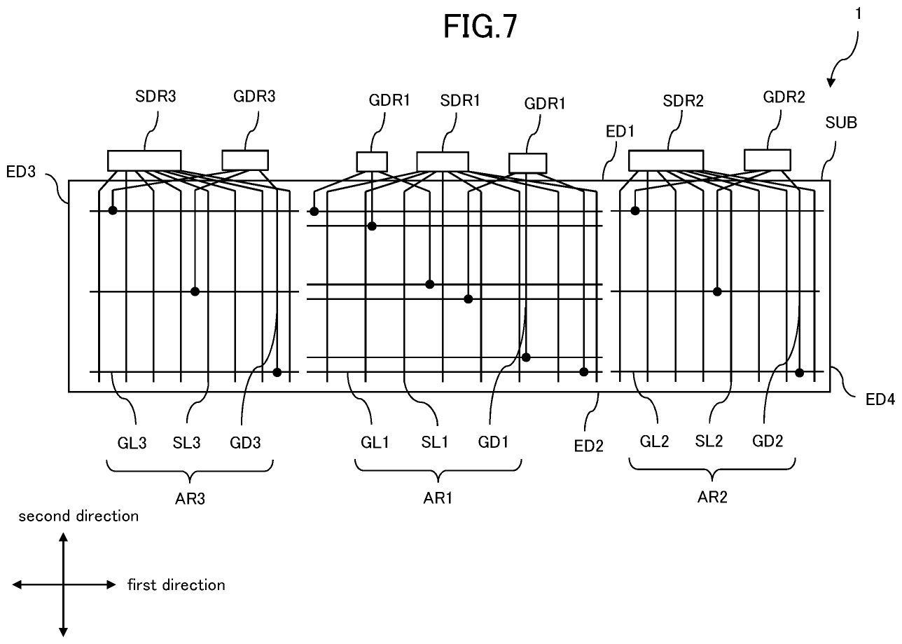

As illustrated in FIG. 7, second TFT array AR2 may further include a plurality of second gate lead-out lines GD2, which extend in the second direction and are connected to the plurality of second gate lines GL2. The second gate lead-out line GD2 extends between two second source lines SL2 adjacent to each other. Second gate driver GDR2 is connected to the plurality of second gate lead-out lines GD2, and the gate signal output from the second gate driver GDR2 is supplied to the plurality of second gate lines GL2 through the plurality of second gate lead-out lines GD2.

With this configuration, second gate driver GDR2 can be disposed along first end side ED1 or second end side ED2 extending in the first direction. As a result, the configuration in which each drive circuit is not disposed along the end side (in the example of FIG. 7, fourth end side ED4) extending in the second direction can be constructed, and the space saving of the frame region can desirably further be achieved.

Similarly, as illustrated in FIG. 7, third TFT array AR3 may further include a plurality of third gate lead-out lines GD3, which extend in the second direction and are connected to the plurality of third gate lines GL3. Third gate lead-out line GD3 extends between two third source lines SL3 adjacent to each other. Third gate driver GDR3 is connected to the plurality of third gate lead-out lines GD3, and the gate signal output from third gate driver GDR3 is supplied to the plurality of third gate lines GL3 through the plurality of third gate lead-out lines GD3.

With this configuration, third gate driver GDR3 can be disposed along first end side ED1 or second end side ED2 extending in the first direction. As a result, the configuration in which each drive circuit is not disposed along the end side (in the example of FIG. 7, third end side ED3) extending in the second direction can be constructed, and the space saving of the frame region can desirably further be achieved.

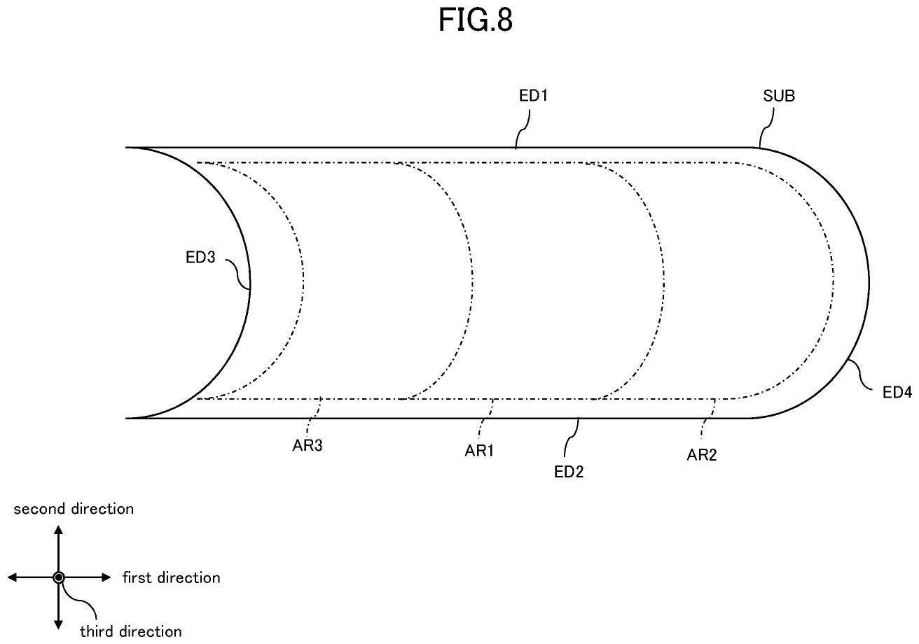

Further, display device 1 is configured such that each drive circuit is disposed only along the end side extending in the first direction, but not disposed along the end side extending in the second direction, which allows an applicable range of the shape that can be taken by display device 1 to be widened. For example, as illustrated in FIG. 8, in first substrate SUB, it is difficult to dispose each drive circuit along the end side extending in the second direction in the configuration in which the end side (third end side ED3 and fourth end side ED4) extending in the second direction is curved in a third direction intersecting the first and second directions. However, as illustrated in FIG. 7, each drive circuit can be disposed to avoid the curved end side when not disposed along the end side extending in the second direction. For this reason, in first substrate SUB, it can be applied to the configuration in which the end side extending in the second direction is curved in the third direction.

In the example of FIG. 7, each drive circuit is disposed along first end side ED1. Alternatively, at least one of the drive circuits may be disposed along second end side ED2. However, the space saving of the frame region is desirably achieved by the configuration in which each drive circuit is disposed along the common end side (first end side ED1 or second end side ED2).

However, as illustrated in FIG. 6, the wiring capacitance can be reduced when second TFT array AR2 and third TFT array AR3 do not include second gate lead-out line GD2 and third gate lead-out line GD3, which is desirable from the viewpoint of high speed drive. Thus, when second TFT array AR2 and third TFT array AR3 need to be driven at high speed, it is desirable to have the following configuration as illustrated in FIG. 6. First gate lead-out line GD1 extending in the second direction is provided for first TFT array AR1 (that may further include another TFT array) disposed between at least two other TFT arrays. Then, first source driver SDR1 and first gate driver GDR1 are disposed along the end side (first end side ED1 or second end side ED2) extending in the first direction. Second gate lead-out line GD2 extending between two second source lines SL2 adjacent to each other and third gate lead-out line GD3 extending between two third source lines SL3 adjacent to each other are not provided for second TFT array AR2 and third TFT array AR3 which are disposed adjacent to the end side (third end side ED3 or fourth end side ED4) extending in the second direction in first substrate SUB. Each drive circuit (second gate driver GDR2, second source driver SDR2, third gate driver GDR3, and third source driver SDR3) is disposed along one of the end sides of the first substrate SUB. With this configuration, it is possible to achieve both the configuration in which each drive circuit is not disposed between the TFT arrays and the configuration in which the wiring capacitance is reduced in the TFT array disposed adjacent to the end side extending in the second direction in first substrate SUB.

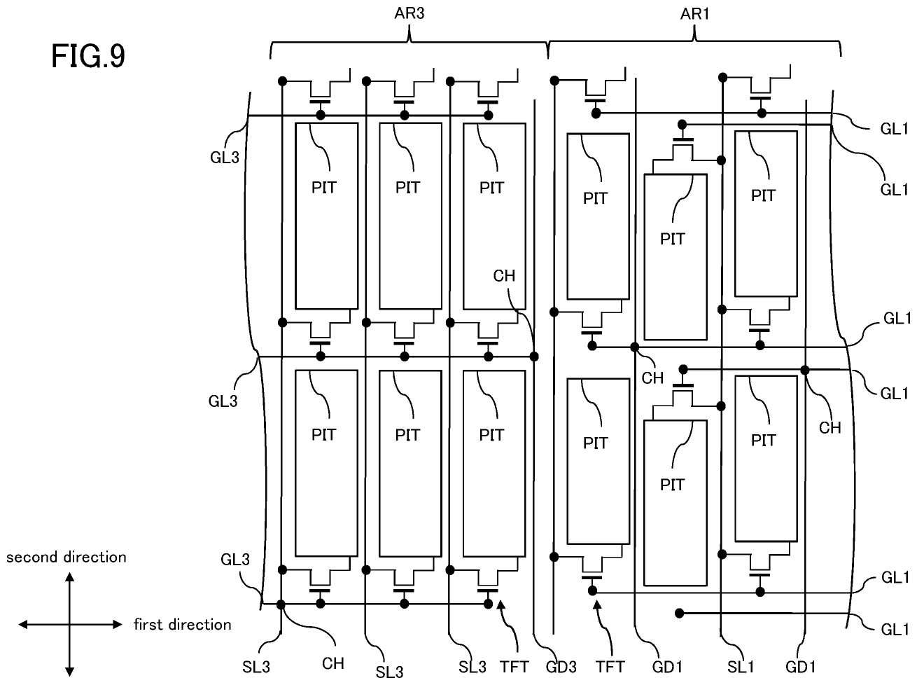

FIG. 9 is an enlarged schematic diagram illustrating the boundary portion between first TFT array AR1 and third TFT array AR3 in FIG. 7. In the example of FIG. 9, first gate lead-out lines GD1 are disposed at a ratio of two first gate lead-out lines GD1 to three pixel electrodes PIT arrayed in the first direction in the first TFT array AR1, and third gate lead-out line GD3 is disposed at a ratio of one third gate lead-out line GD3 to three pixel electrodes PIT arrayed in the first direction in third TFT array AR3. In first TFT array AR1, first source line SL1 and first gate lead-out line GD1 are alternately arrayed between two pixel electrodes PIT adjacent to each other in the plurality of pixel electrodes PIT arrayed in the first direction. In third TFT array AR3, one third source line SL3, one third source line SL3, one third source line SL3, and one third gate lead-out line GD3 are repeatedly arranged in order between two pixel electrodes PIT adjacent to each other in the plurality of pixel electrodes PIT arrayed in the first direction. First gate lead-out line GD1 is electrically connected to first gate line GL1 through contact hole CH, and third gate lead-out line GD3 is electrically connected to third gate line GL3 through contact hole CH In the example of FIG. 9, the number of first gate lines GL1 per unit area in the region where first TFT array AR1 is disposed is larger than the number of third gate lines GL3 per unit area in the region where third TFT array AR3 is disposed. Similarly, the number of first gate lines GL1 per unit area in the region where first TFT array AR1 is disposed is larger than the number of second gate line GL2 per unit area in the region where second TFT array AR2 is disposed. In the example of FIG. 9, the number of first source lines SL1 per unit area in the region where first TFT array AR1 is disposed is smaller than the number of third source lines SL3 per unit area in the region where third TFT array AR3 is disposed. Similarly, the number of first source lines SL1 per unit area in the region where first TFT array AR1 is disposed is smaller than the number of second source lines SL2 per unit area in the region where second TFT array AR2 is disposed. In the example of FIG. 9, the distance in the second direction between two first gate lines GL1 between which one pixel electrode PIT is interposed in first TFT array AR1 is shorter than the distance in the second direction between two third gate lines GL3 between which one pixel electrode PIT is interposed in third TFT array AR3. Similarly, the distance in the second direction between two first gate lines GL1 between which one pixel electrode PIT is interposed in first TFT array AR1 is shorter than the distance in the second direction between two second gate lines GL2 between which one pixel electrode PIT is interposed in second TFT array AR2. In FIG. 7, although the limited numbers of source lines and gate lines are illustrated for convenience, actually, display device 1 may have larger numbers of source lines and gate lines.

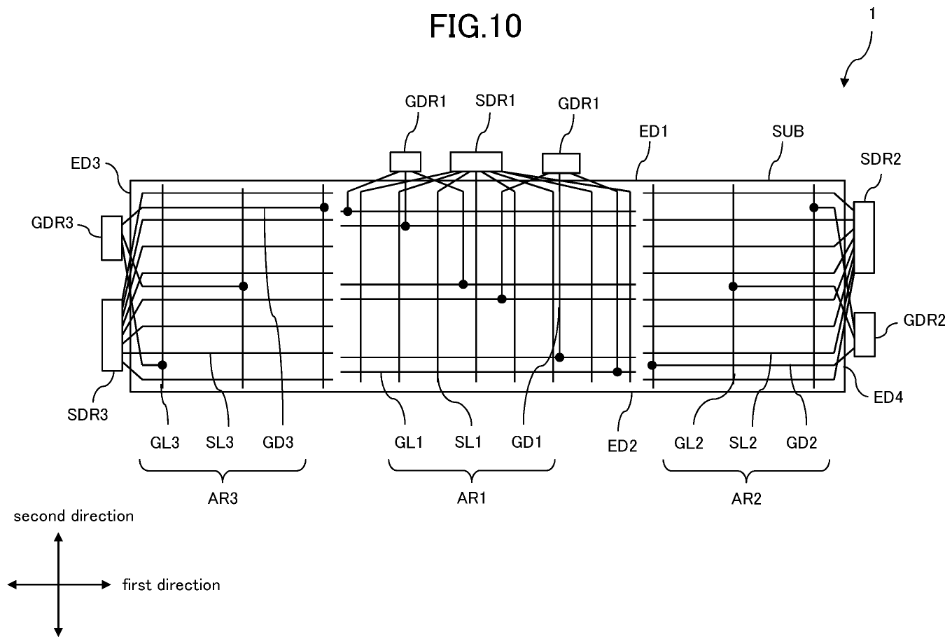

As illustrated in FIG. 10, in second TFT array AR2, the plurality of second source lines SL2 may extend in the first direction, the plurality of second gate lines GL2 may extend in the second direction, and the plurality of second gate lead-out lines GD2 may extend in the first direction.

With this configuration, second source driver SDR2 and second gate driver GDR2 can be disposed along the end side (in the example of FIG. 10, fourth end side ED4) extending in the second direction.

Similarly, as illustrated in FIG. 10, in third TFT array AR3, the plurality of third source lines SL3 may extend in the first direction, the plurality of third gate lines GL3 may extend in the second direction, and the plurality of third gate lead-out lines GD3 may extend in the first direction.

With this configuration, third source driver SDR3 and third gate driver GDR3 can be disposed along the end side (in the example of FIG. 10, third end side ED3) extending in the second direction.

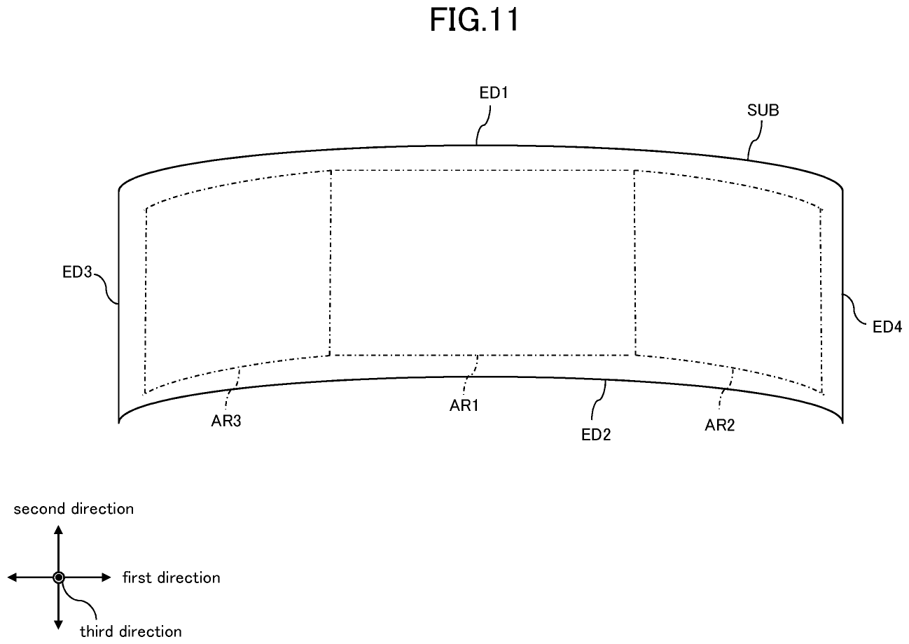

As described above, each drive circuit (second source driver SDR2, second gate driver GDR2, third source driver SDR3, and third gate driver GDR3) connected to second TFT array AR2 and third TFT array AR3 is not disposed along the end side extending in the first direction in the region where second TFT array AR2 and third TFT array AR3 are formed, while each drive circuit is disposed only along the second direction, which allows the applicable range of the shape that can be taken by display device 1 to be widened. For example, as illustrated in FIG. 11, in the configuration in which the end sides (first end side ED1, second end side ED2) extending in the first direction are curved in the third direction intersecting the first and second directions and in which a curvature becomes high in the region where second TFT array AR2 and third TFT array AR3 are formed, failures such as poor connection are easily generated when each drive circuit is disposed along the end side extending in the first direction in the region. However, as in the configuration of FIG. 10, each drive circuit connected to second TFT array AR2 and third TFT array AR3 is disposed only along the end side extending in the second direction, which allows each drive circuit to be disposed while avoiding the region having a high curvature at the curved end side (first end side ED1, second end side ED2).

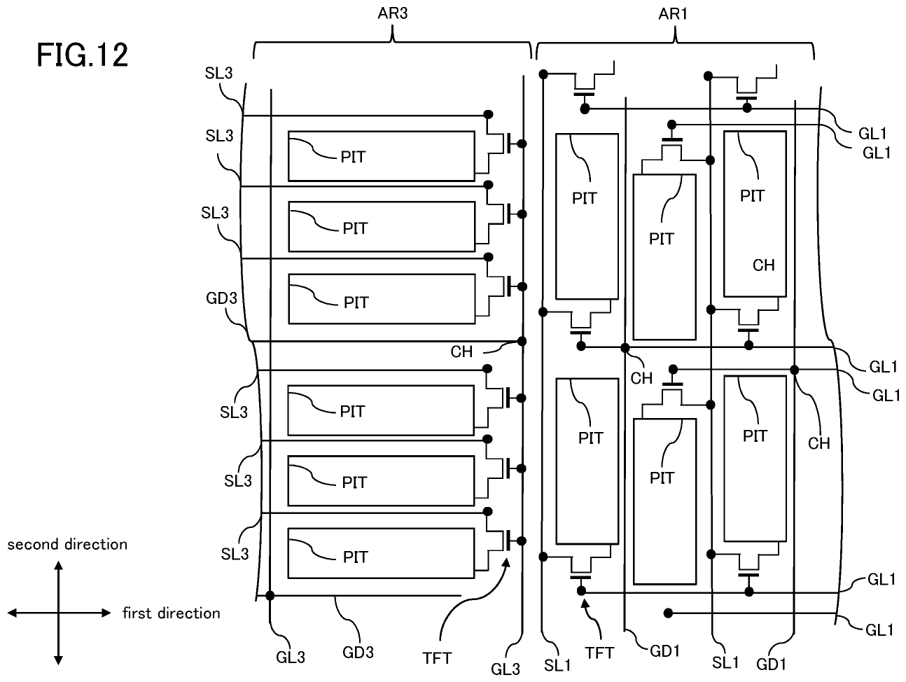

FIG. 12 is an enlarged schematic diagram illustrating the boundary portion between first TFT array AR1 and third TFT array AR3 in FIG. 10. In the example of FIG. 12, first gate lead-out lines GD1 are disposed at a ratio of two first gate lead-out lines GD1 to three pixel electrodes PIT arrayed in the first direction in the first TFT array AR1, and third gate lead-out line GD3 is disposed at a ratio of one third gate lead-out line GD3 to three pixel electrodes PIT arrayed in the second direction in third TFT array AR3. First gate lead-out line GD1 is electrically connected to first gate line GL1 through contact hole CH, and third gate lead-out line GD3 is electrically connected to third gate line GL3 through contact hole CH. In the example of FIG. 12, the number of first gate lines GL1 per unit area in the region where first TFT array AR1 is disposed is larger than the number of third gate lines GL3 per unit area in the region where third TFT array AR3 is disposed. Similarly, the number of first gate lines GL1 per unit area in the region where first TFT array AR1 is disposed is larger than the number of second gate line GL2 per unit area in the region where second TFT array AR2 is disposed. In the example of FIG. 12, the number of first source lines SL1 per unit area in the region where first TFT array AR1 is disposed is smaller than the number of third source lines SL3 per unit area in the region where third TFT array AR3 is disposed. Similarly, the number of first source lines SL1 per unit area in the region where first TFT array AR1 is disposed is smaller than the number of second source lines SL2 per unit area in the region where second TFT array AR2 is disposed. In the example of FIG. 12, the distance in the second direction between two first gate lines GL1 between which one pixel electrode PIT is interposed in first TFT array AR1 is equal to the distance in the second direction between two third source lines SL3 between which three pixel electrodes PIT are interposed in third TFT array AR3. Similarly, the distance in the second direction between two first gate lines GL1 between which one pixel electrode PIT is interposed in first TFT array AR1 is equal to the distance in the second direction between two second source lines SL2 between which three pixel electrodes PIT are interposed in second TFT array AR2. In FIG. 10, although the limited numbers of source lines and gate lines are illustrated for convenience, actually, display device 1 may have larger numbers of source lines and gate lines.

In the examples described above with reference to FIGS. 1 to 12, each TFT array is connected to a different drive circuit, so that a refresh rate (image rewriting frequency per unit time) of each TFT array can be varied. For example, display as a car navigation system is performed in the region where first TFT array AR1 is formed, and display as a camera monitor system is performed in the region where second TFT array AR2 and third TFT array AR3 are formed. In such cases, the drive speed required for second TFT array AR2 and third TFT array AR3 is higher than the drive speed required for first TFT array AR1. For this reason, the refresh rate (for example, 120 Hz) in second TFT array AR2 and third TFT array AR3 may be higher than the refresh rate (for example, 60 Hz) in first TFT array AR1.

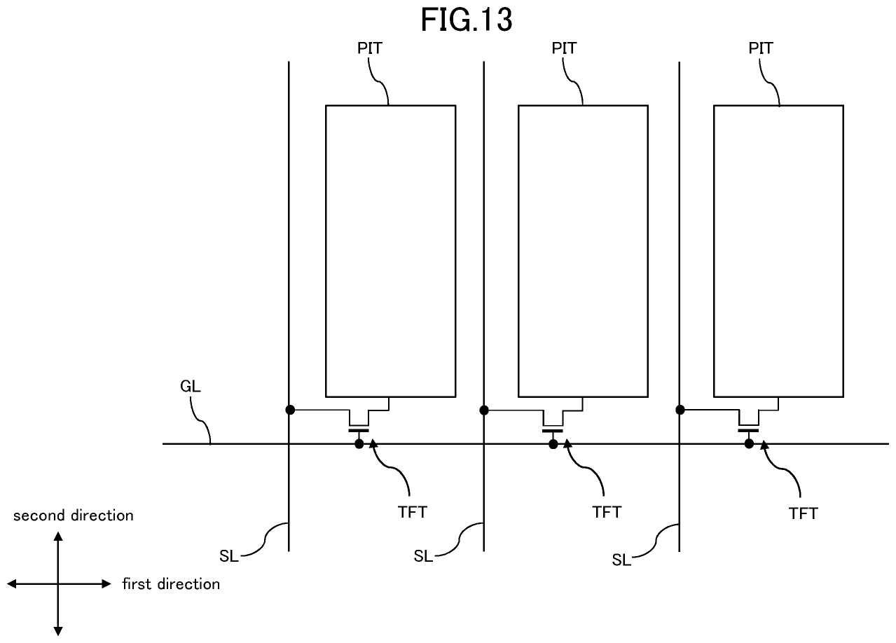

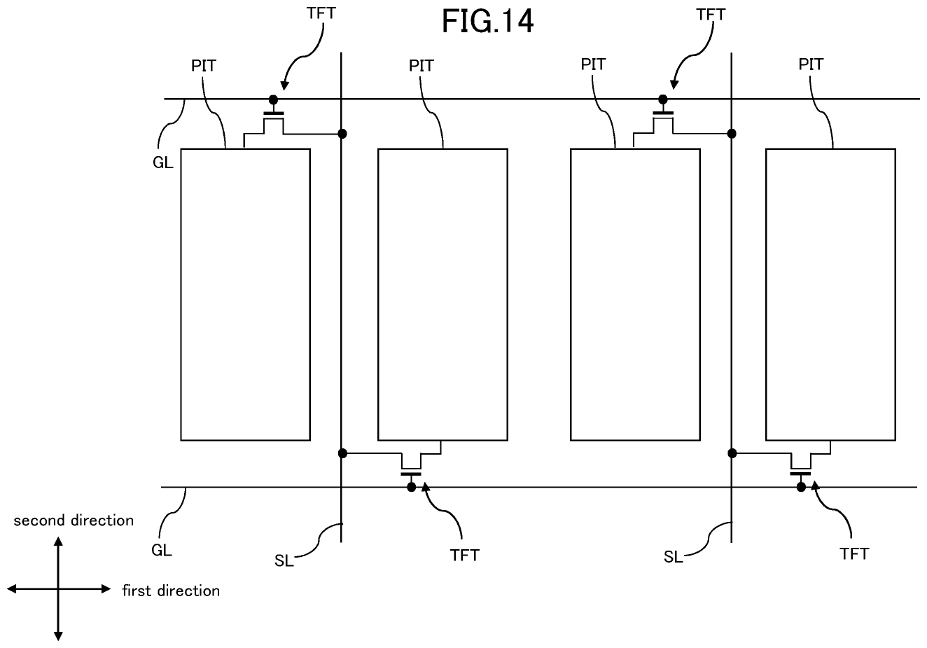

A drive rate of each TFT array may be varied. A concept of the drive rate will be described below with reference to FIGS. 13 and 14.

In the example of FIG. 13, each pixel electrode PIT is connected to one source line SL through a thin film transistor TFT. Consequently, at timing when the gate signal is supplied from the gate line GL to turn on each thin film transistor TFT, the source signal is supplied from each source line SL to each pixel electrode PIT without time division.

On the other hand, in the example of FIG. 14, two pixel electrodes PIT adjacent to each other are connected to common one source line SL through thin film transistor TFT. Two pixel electrodes PIT adjacent to each other are connected to different gate lines GL, and turned on at different timings according to the transmission of the gate signal. The source signal transmitted to common one source line SL is time-divided and supplied to two pixel electrodes PIT adjacent to each other.

As described above, the configuration in which one source signal is time-divided and supplied to n pixel electrodes PIT is defined as the configuration having a drive rate n times that of the configuration in which the source signal is supplied to pixel electrodes PIT without time division. That is, the configuration in FIG. 14 has a drive rate twice that of the configuration in FIG. 13. In other words, the drive rate is enhanced with increasing number of gate lines connected to each pixel electrode PIT arranged in the extending direction of the plurality of gate lines. For example, in the example of FIG. 13, pixel electrodes PIT disposed in one row in the first direction are connected to one gate line GL. On the other hand, in the example illustrated in FIG. 14, the pixel electrodes PIT arrayed in one row in the first direction are connected to two gate lines GL. Assuming that the example in FIG. 13 has the drive rate of 1, the example in FIG. 14 has the drive rate of 2. Thus, the drive rate of the example in FIG. 14 is higher than the drive rate of the example in FIG. 13.

The number of source lines SL can be decreased with increasing drive rate, so that the number of source drivers or the number of terminals provided in the source drivers can be decreased to achieve cost reduction.

On the other hand, the time for which the source signal is written in one pixel electrode PIT is shortened with increasing drive rate. That is, in the configuration of the drive rate of n times, the time for which the source signal is written in one pixel electrode PIT becomes 1/n times. For this reason, an upper limit of the drive rate exists depending on performance of thin film transistor TFT. In particular, in the region having the high refresh rate, the time that is written to one pixel electrode PIT is shortened even at the same drive rate, so that the upper limit of the drive rate is lower than that in the region having the low refresh rate. For this reason, for example, when the refresh rate in first TFT array AR1 is lower than the refresh rate in second TFT array AR2, the drive rate in first TFT array AR1 is desirably set higher than the drive rate of second TFT array AR2. With this configuration, priority is given to the refresh rate in second TFT array AR2 in which the high-speed drive is required, and priority is given to cost reduction in first TFT array AR1 in which the high-speed drive is not required.

For the configuration in which the drive rate in first TFT array AR1 is higher than the drive rate of second TFT array AR2 as illustrated in FIGS. 6, 7 and 10, the number of first gate lines GL1 per unit area in the region where first TFT array AR1 is disposed is larger than the number of second gate lines GL2 per unit area in the region where second TFT array AR2 is disposed. The number of first source lines SL1 per unit area in the region where first TFT array AR1 is disposed is smaller than the number of second source lines SL2 per unit area in the region where second TFT array AR2 is disposed.

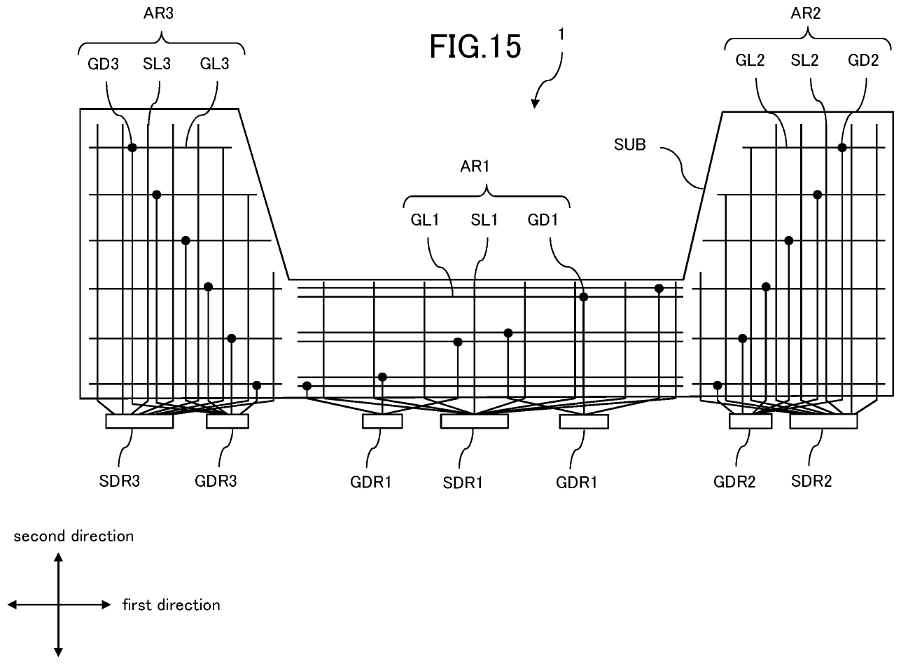

In the example of FIG. 15, the width in the second direction in the region where first TFT array AR1 is disposed is smaller than the width in the second direction in the region in where second TFT array AR2 is disposed. For this reason, the number of pixels in a gate scan direction (second direction) in the region where first TFT array AR1 is disposed is smaller than the number of pixels in the gate scan direction (second direction) in the region where second TFT array AR2 is disposed. As a result, even if thin film transistor TFT having the same performance is used in each TFT array, the refresh rate in first TFT array AR1 can be set higher than the refresh rate in second TFT array AR2. The drive rate in first TFT array AR1 can be set higher than the drive rate in second TFT array AR2. In the example of FIG. 15, the width in the second direction in the region where first TFT array AR1 is disposed is smaller than the width in the second direction in the region where second TFT array AR2 is disposed. Alternatively, the width in the second direction in the region where second TFT array AR2 is disposed may be smaller than the width in the second direction in the region where first TFT array AR1 is disposed. In this configuration, the refresh rate in second TFT array AR2 may be set higher than the refresh rate in first TFT array AR1. The drive rate in second TFT array AR2 may be set higher than the drive rate in first TFT array AR1.

In the examples described above with reference to FIGS. 1 to 15, the number of pixels per unit area in the region where each TFT array is disposed can be varied because the TFT arrays are isolated from each other. For example, when resolution higher than that of first TFT array AR1 is required in second TFT array AR2, the number of pixels per unit area in the region where second TFT array AR2 is disposed may be larger than the number of pixels per unit area in the region where first TFT array AR1 is disposed.

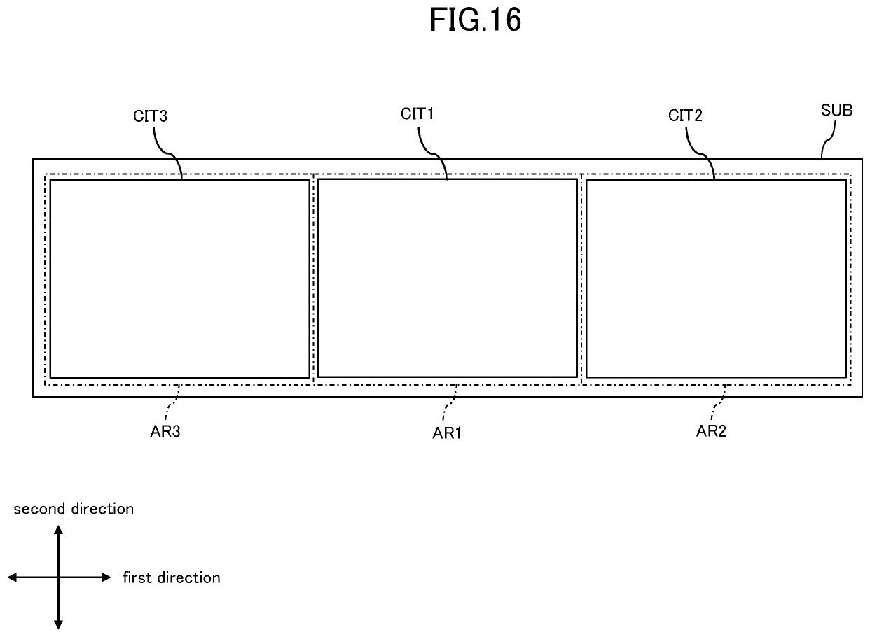

Display device 1 of the exemplary embodiment includes a common electrode disposed opposite to the plurality of pixel electrodes in first substrate SUB. As illustrated in FIG. 16 that is a schematic diagram illustrating an arrangement example of the common electrodes, first common electrode CIT1 opposed to first TFT array AR1 and second common electrode CIT2 opposed to second TFT array AR2 are provided separately from each other, and disposed apart from each other so as to be electrically isolated, and voltage applied to first common electrode CIT1 may differ from voltage applied to second common electrode CIT2. For example, the time for which the source signal is written in pixel electrode PIT of second TFT array AR2 may become shorter than the time for which the source signal is written in pixel electrode PIT of first TFT array AR1 in combination with the drive rate and the refresh rate. In such cases, it is conceivable that a thin film transistor having an area larger than that of thin film transistor TFT used in first TFT array AR1 is used as thin film transistor TFT used in second TFT array AR2. When the area of thin film transistor TFT is increased, capacitive coupling between thin film transistor TFT and gate line GL is increased, so that an optimal common voltage is lowered. For this reason, when the thin film transistor having the area larger than that of thin film transistor TFT used in first TFT array AR1 is used as thin film transistor TFT used in second TFT array AR2, the voltage applied to second common electrode CIT2 opposed to second TFT array AR2 is desirably set lower than the voltage applied to common electrode CIT1 opposed to first TFT array AR1. Similarly, third common electrode CIT3 opposed to third TFT array AR3 is provided separately from first common electrode CIT1 and second common electrode CIT2, and the voltage applied to third common electrode CIT3 may differ from the voltage applied to first common electrode CIT1 and the voltage applied to second common electrode CIT2.

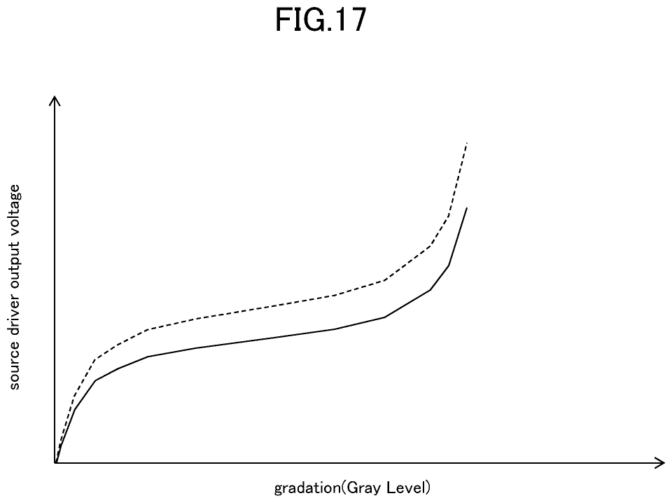

When a size of thin film transistor TFT in each TFT array is varied, the voltage required to obtain desired brightness changes. Thus, a gradation characteristic of the source signal supplied to each TFT array may be varied. FIG. 17 is a conceptual view illustrating an example in which a gradation characteristic of a first source signal supplied to first TFT array AR1 and a gradation characteristic of a second source signal supplied to second TFT array AR2 are different from each other. In FIG. 17, a solid line indicates a relationship (first gradation characteristic) between the voltage output from first source driver SDR1 and gradation, and a broken line indicates a relationship (second gradation characteristic) between the voltage output from second source driver SDR2 and gradation. For example, when thin film transistor TFT having the area larger than that of thin film transistor TFT used in first TFT array AR1 is used as thin film transistor TFT used in second TFT array AR2, a voltage value required for obtaining the desired brightness is increased. Thus, as illustrated in FIG. 17, the voltage output from second source driver SDR2 is desirably set higher than the voltage output from first source driver SDR1 when the output voltages are compared to each other at the same gradation.

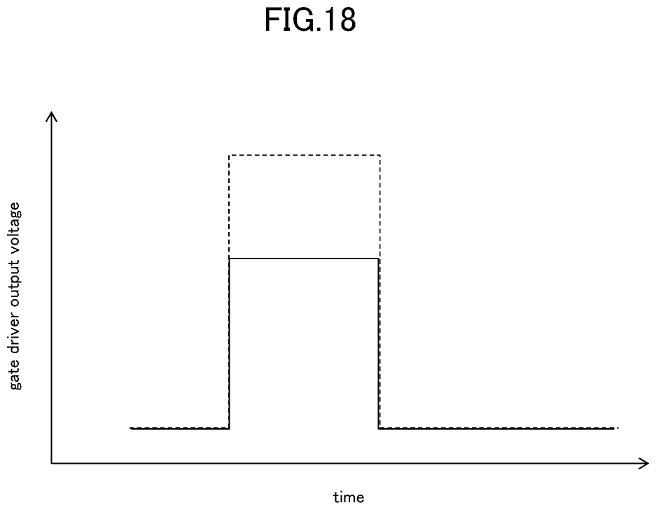

An amplitude of the gate signal supplied to each TFT array may be varied according to the refresh rate in each TFT array. In FIG. 18, the solid line indicates the relationship between the time and the voltage output from first gate driver GDR1, and the broken line indicates the relationship between the time and the voltage output from second gate driver GDR2. For example, when the refresh rate of second TFT array AR2 is higher than the refresh rate of first TFT array AR1, the voltage output from second gate driver GDR2 is desirably set higher than the voltage output from first gate driver GDR1. With this configuration, the amplitude of the second gate signal supplied to second gate line GL2 can be made larger than the amplitude of the first gate signal supplied to first gate line GL1, and a high response speed can be obtained in second TFT array AR2.

When a still image as in a car navigation system is displayed in the region where first TFT array AR1 is formed, the amplitude of the first gate signal supplied to first gate line GL1 is desirably smaller than the amplitude of the second gate signal supplied to second gate line GL2 in order to prevent the generation of unevenness in the display image.

FIG. 19 is a schematic diagram illustrating an arrangement example of liquid crystal layer LC of the exemplary embodiment and seal member L which is disposed around liquid crystal layer LC to bond first substrate SUB and the counter substrate disposed opposite to first substrate SUB. In the example of FIG. 19, even if the plurality of TFT arrays are formed in first substrate SUB, one liquid crystal layer LC is formed in the whole of first substrate SUB in planar view regardless of the boundary positions of the plurality of TFT arrays. With this configuration, the seal member is not disposed between the TFT arrays, so that the visibility of the boundary between the plurality of TFT arrays can further be decreased.

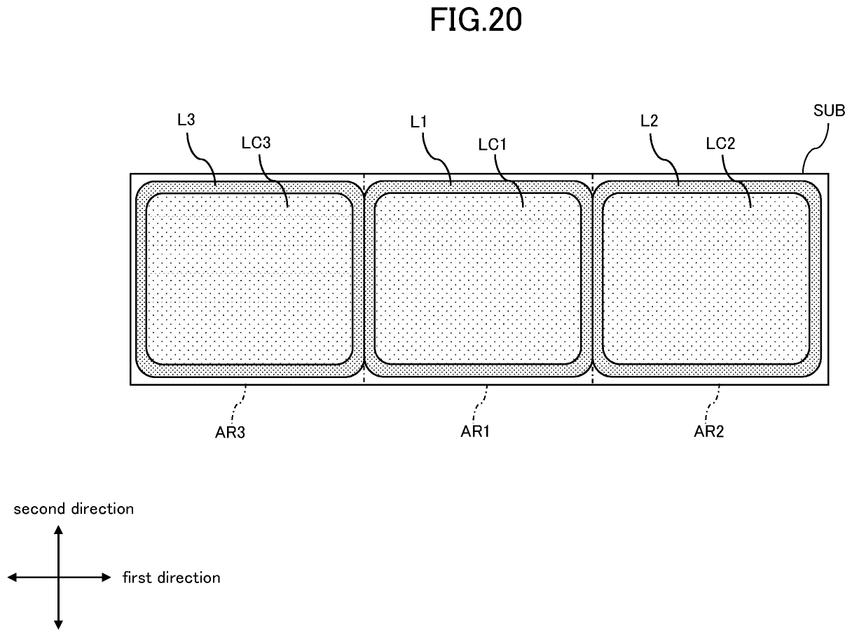

However, as illustrated in FIG. 20, the liquid crystal layer may separately be provided in each TFT array. Specifically, first liquid crystal layer LC1 may be formed in the region where first TFT array AR1 is formed, and first seal member L1 may be formed around first liquid crystal layer LC1. Similarly, second liquid crystal layer LC2 and second seal member L2 disposed around second liquid crystal layer LC2 may be formed in the region where second TFT array AR2 is formed, and third liquid crystal layer LC3 and third seal member L3 disposed around third liquid crystal layer LC3 may be formed in the region where third TFT array AR3 is formed. With the configuration in FIG. 20, a liquid crystal material used for first liquid crystal layer LC1 can be different from a liquid crystal material used for second liquid crystal layer LC2. For this reason, for example, when the refresh rate in second TFT array AR2 is higher than the refresh rate in first TFT array AR1, desirably, a liquid crystal material suitable for high-speed drive is used for second liquid crystal layer LC2, and a normal liquid crystal material is used for first liquid crystal layer LC1. For example, a material having viscosity lower than that of the liquid crystal material used for first liquid crystal layer LC1 can be used as the liquid crystal material used for second liquid crystal layer LC2.

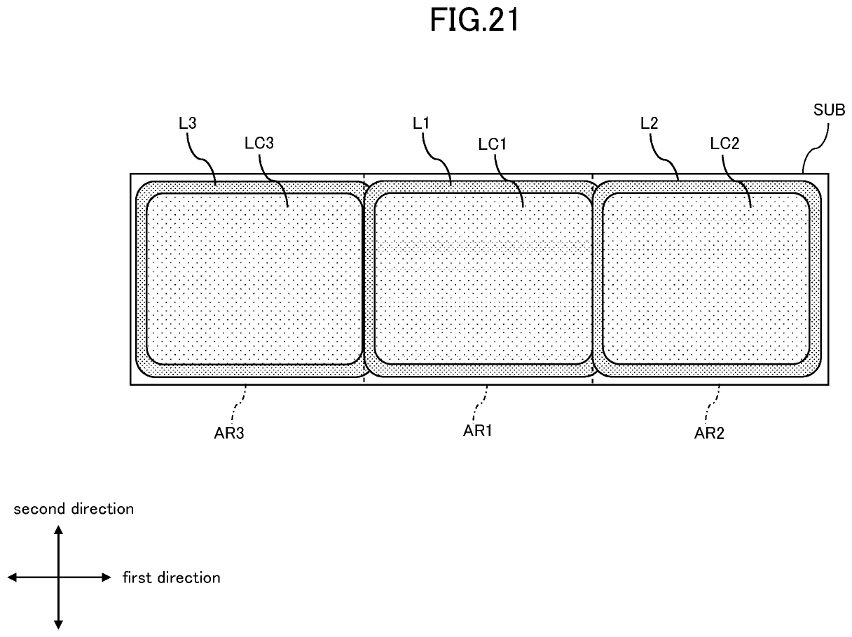

As illustrated in FIG. 21, only one side of first seal member L1 may be disposed between first TFT array AR1 and third TFT array A113, and only one side of second seal member L2 may be disposed between first TFT array AR1 and second TFT array A112. With this configuration, the distance in the first direction between the TFT arrays is set to the width of one seal member disposed between the TFT arrays, so that the visibility of the boundary between the plurality of TFT arrays can be decreased as compared with the configuration in FIG. 20.

In the above, the specific embodiments of the present application have been described, but the present application is not limited to the above-mentioned embodiments, and various modifications may be made as appropriate without departing from the spirit of the present application.

What is claimed is:

1. A display device comprising:
a first substrate; and
a first TFT array and a second TFT array that are formed on the first substrate,
wherein the first TFT array includes:
a plurality of first gate lines extending in a first direction; and
a plurality of first source lines extending in a second direction intersecting the first direction,
the second TFT array includes:
a plurality of second gate lines extending in one of the first direction and the second direction; and
a plurality of second source lines extending in the other of the first direction and the second direction, and
the first TFT array and the second TFT array are electrically isolated from each other, and disposed adjacent to each other in the first direction.

2. The display device according to claim 1, wherein the first TFT array further includes a plurality of first gate lead-out lines that extend in the second direction and are connected to the plurality of first gate lines.

3. The display device according to claim 2, further comprising:
a first gate driver that supplies a gate signal to the plurality of first gate lines; and
a first source driver that supplies a source signal to the plurality of first source lines,
wherein the first gate driver and the first source driver are disposed along an end side extending in the first direction among end sides of the first substrate.

4. The display device according to claim 3, further comprising:
a second gate driver that supplies a gate signal to the plurality of second gate lines, the plurality of second gate lines extending in the first direction; and
a second source driver that supplies a source signal to the plurality of second source lines, the plurality of second source lines extending in the second direction,
wherein the second gate driver is disposed along an end side extending in the second direction among the end sides of the first substrate, and
the second source driver is disposed along the end side extending in the first direction among the end sides of the first substrate.

5. The display device according to claim 4, further comprising:
a third TFT array including a plurality of third gate lines extending in the first direction and a plurality of third source lines extending in the second direction;
a third gate driver that supplies a gate signal to the plurality of third gate lines; and
a third source driver that supplies a source signal to the plurality of third source lines,
wherein the third TFT array is formed on the first substrate, and is electrically isolated from the first TFT array and the second TFT array,
the third TFT array is disposed adjacent to the first TFT array and on an opposite side to the second TFT array with respect to the first TFT array,
the third gate driver is disposed along an end side opposed to the end side along which the second gate driver is disposed among the end sides of the first substrate, and
the third source driver is disposed along the end side extending in the first direction among the end sides of the first substrate.

6. The display device according to claim 1, further comprising:
a second gate driver that supplies a gate signal to the plurality of second gate lines; and
a second source driver that supplies a source signal to the plurality of second source lines,
wherein the plurality of second gate lines extend in the first direction,
the plurality of second source lines extend in the second direction,
the second TFT array further includes a plurality of second gate lead-out lines that extend in the second direction and are connected to the plurality of second gate lines, and
the second gate driver and the second source driver are disposed along the end side extending in the first direction among the end sides of the first substrate.

7. The display device according to claim 6, wherein in the first substrate, an end side extending in the second direction is curved.

8. The display device according to claim 1, further comprising:
a second gate driver that supplies a gate signal to the plurality of second gate lines; and
a second source driver that supplies a source signal to the plurality of second source lines,
wherein the plurality of second source lines extend in the first direction,
the plurality of second gate lines extend in the second direction,
the second TFT array further includes a plurality of second gate lead-out lines that extend in the first direction and are connected to the plurality of second gate lines, and
the second gate driver and the second source driver are disposed along an end side extending in the second direction among the end sides of the first substrate.

9. The display device according to claim 8, wherein in the first substrate, an end side extending in the first direction is curved.

10. The display device according to claim 1, wherein a refresh rate in the first TFT array is lower than a refresh rate in the second TFT array.

11. The display device according to claim 10, wherein a drive rate in the first TFT array is higher than a drive rate in the second TFT array.

12. The display device according to claim 1, wherein a width in the second direction in a region where the first TFT array is disposed is smaller than a width in the second direction in the region where the second TFT array is disposed.

13. The display device according to claim 12, wherein a refresh rate in the first TFT array is higher than a refresh rate in the second TFT array.

14. The display device according to claim 12, wherein a drive rate in the first TFT array is higher than a drive rate in the second TFT array.

15. The display device according to claim 1, wherein
the number of the first gate lines per unit area in a region where the first TFT array is disposed is larger than the number of the second gate lines per unit area in a region where the second TFT array is disposed, and
the number of the first source lines per unit area in the region where the first TFT array is disposed is smaller than the number of the second source lines per unit area in the region where the second TFT array is disposed.

16. The display device according to claim 1, wherein the number of pixels per unit area in a region where the first TFT array is disposed is smaller than the number of pixels per unit area in a region where the second TFT array is disposed.

17. The display device according to claim 1, further comprising:
a first common electrode opposed to the first TFT array; and
a second common electrode opposed to the second TFT array,
wherein voltage applied to the first common electrode is different from voltage applied to the second common electrode.

18. The display device according to claim 1, further comprising:
a first source driver that supplies a first source signal to the plurality of first source lines; and
a second source driver that supplies a second source signal to the plurality of second source lines,
wherein the first source driver supplies the first source signal based on a first gradation characteristic, and
the second source driver supplies the second source signal based on a second gradation characteristic that is different from the first gradation characteristic.

19. The display device according to claim 1, further comprising:
a first gate driver that supplies a first gate signal to the plurality of first gate lines; and
a second gate driver that supplies a second gate signal to the plurality of second gate lines,
wherein an amplitude of the second gate signal is greater than an amplitude of the first gate signal.

20. The display device according to claim 19, wherein a refresh rate in the second TFT array is higher than a refresh rate in the first TFT array.
